(19) United States
(12) Patent Application Publication
(10) Pub. No.: US 2019/0036082 A1
(43) Pub. Date: Jan. 31, 2019

(54) INTEGRATED SUBSTRATE, METHOD FOR THE MANUFACTURE THEREOF, AND OPTICAL DEVICES COMPRISING THE INTEGRATED SUBSTRATE

(71) Applicant: SABIC Global Technologies B.V., Bergen op Zoom (NL)

(72) Inventors: Yingjun Cheng, Shanghai (CN); Libo Wu, Shanghai (CN); Andries Jakobus Petrus van Zyl, Bergen op Zoom (NL); Wei Feng, Shanghai (CN)

(21) Appl. No.: 16/073,532

(22) PCT Filed: Jan. 27, 2017
(86) PCT No.: PCT/IB2017/050453

§ 371 Date: Jul. 27, 2018

Related U.S. Application Data
(60) Provisional application No. 62/288,526, filed on Jan. 29, 2016.

(51) Int. Cl. H01L 51/52; H01L 51/00; H01L 51/56

(52) U.S. Cl. CPC H01L 51/5268; H01L 51/0096; H01L 51/5275; H01L 2251/558; H01L 51/5206; H01L 2251/5369; H01L 51/56

(57) ABSTRACT

An integrated substrate includes a substrate having a first surface and a second surface, and a light extraction layer disposed on the first surface of the substrate. The light extraction layer includes a polyimide having a glass transition temperature of greater than 200 to 350° C., and a plurality of nanoparticles, and the light extraction layer has a refractive index of 1.7 to 2.0. A method of manufacturing the integrated substrate is also disclosed, where the method includes applying the light extraction layer on the first surface of the substrate. An optical device including the integrated substrate is also described.

### BACKGROUND

Electroluminescent illuminating devices, such as organic light emitting diodes (OLEDs) and quantum dot light emitting diodes (QD-LEDs), have gained increasing attention due to the many advantages and potential applications in, for example, flat panel displays and lighting. Typically, light emitting diodes have a multilayer structure including an anode, a hole injection layer, a hole transport layer, an emitting layer, an electron transport layer, an electron injection layer, and a cathode. The optical properties and the structure of the electrodes are dominant factors in the out-coupling efficiency and optical properties of the light emitting diodes. The distinction in the refractive index between the various layers of a light emitting diode can be large (i.e., mismatched), which allows for only about 20% of light to be emitted from the front of the device. If light refraction and reflection at the interfaces between each layer of the light emitting diode is lowered and the light inside the device is out-coupled again by improving the refractive index of each layer, the luminous efficiency of the light emitting diode can be improved.

Accordingly, there remains a continuing need for an improved material that possesses transparency and high heat resistance and that can improve the light extraction efficiency of an illuminating device, in particular an OLED or a QD-LED. It would be a further advantage if such a material could withstand high temperature processing.

### BRIEF DESCRIPTION

An integrated substrate comprises a substrate having a first surface and a second surface opposite the first surface; and a light extraction layer disposed on the first surface of the substrate, the light extraction layer comprising a polyimide having a glass transition temperature of greater than 200 to 350° C., preferably 250 to 350° C., more preferably 300 to 350° C.; and a plurality of nanoparticles; wherein the light extraction layer has a refractive index of 1.7 to 2.0, preferably 1.8 to 1.9.

A method of manufacturing the integrated substrate comprises applying the light extraction layer to the first surface of the substrate.

An optical device comprises an integrated substrate comprising, a substrate having a first surface and a second surface; a light extraction layer disposed on the first surface of the substrate, the light extraction layer comprising a polyimide having a glass transition temperature of greater than 200 to 350° C., preferably 250 to 350° C., more preferably 300 to 350° C.; and a plurality of nanoparticles; wherein the light extraction layer has a refractive index of 1.7 to 2.0, preferably 1.8 to 1.9; and an optical component disposed on the light extraction layer on a side opposite the substrate.

The above described and other features are exemplified by the following FIGURE and detailed description.

### BRIEF DESCRIPTION OF THE DRAWINGS

The following FIGURE is an exemplary embodiment wherein the like elements are numbered alike.

FIG. 1 is a schematic representation of a cross-sectional view of an integrated substrate for an optical device.

### DETAILED DESCRIPTION

The present inventors have unexpectedly discovered that an integrated substrate for enhanced light extraction efficiency can be prepared from a substrate and a light extraction layer comprising a polyimide and a plurality of nanoparticles. Advantageously, the combination of the polyimide and the nanoparticles can provide a high refractive index light extraction layer, which can enhance the light extraction efficiency of an electroluminescent device (e.g., a light emitting diode, in particular, an organic light emitting diode, a quantum dot light emitting diode, and the like). Furthermore, the use of the high heat, transparent polyimides renders the integrated substrates compatible with high temperature deposition processes (e.g., sputtering) that can be used to deposit a conductive material (e.g., a transparent electrode (anode) comprising, for example, indium tin oxide).

Accordingly, one aspect of the present disclosure is an integrated substrate. The integrated substrate comprises a substrate having a first surface and a second surface. The second surface is oriented such that it is opposite the first surface of the substrate. In some embodiments, the substrate can be a glass substrate. The glass substrate can be chemically strengthened glass (e.g., CORNING™ GORILLA™ Glass commercially available from Corning Inc., XENSATION™ glass commercially available from Schott AG, DRAGONTRAIL™ glass commercially available from Asahi Glass Company, LTD, and CX-01 glass commercially available from Nippon Electric Glass Company, LTD, and the like), non-strengthened glass such as non-hardened glass including low sodium glass (e.g., CORNING™ WILLOW™ Glass commercially available from Corning Inc. and OA-10G Glass-on-Roll glass commercially available from Nippon Electric Glass Company, LTD, and the like), and sapphire glass commercially available from GT Advanced Technologies Inc. In some embodiments, the glass substrate can be, for example rigid soda-lime floating glass, ultra-thin borosilicate glass (e.g. Corning Willow Glass, Nippon Electric ultra-thin glass), and the like.

In some embodiments, the substrate can be a plastic substrate comprising polyester (including copolymers thereof), polycarbonate (including copolymers thereof), polyether ether ketone, polyarylate, cycloolefin polymer, or a combination comprising at least one of the foregoing. In some embodiments, the plastic substrate can preferably comprise polyethylene terephthalate, polyethylene naphthalate, polynorbornene, polyethersulfone, or a combination comprising at least one of the foregoing.

The substrate can have a thickness of 10 micrometers to 1 millimeter, preferably 50 to 500 micrometers, more preferably 100 to 250 micrometers.

In some embodiments, one or both surfaces of the substrate can be planar and have a smooth structure. In some embodiments, one or both surfaces of the substrate can be a rough surface. In some embodiments, the substrate can have two smooth surfaces, two rough surfaces, or one smooth and one rough surface. In some embodiments, the first surface of the substrate is preferably a roughened surface. In some embodiments, the roughened surface can include micrometer-scaled roughness (e.g., having features having a height of 0.1 to 50 micrometers) to improve light extraction efficiency and uniformity of the emitted light. The surface of the substrate can be roughened by any method that is generally known, for example, by sandblasting the surface of the substrate, by chemically etching the surface of the substrate, by mechanically etching the surface of the substrate, by imprinting the surface of the substrate, or a combination comprising at least one of the foregoing methods to achieve the desired roughness. In some embodiments, the roughened surface can have an irregular or jagged shape. In some embodiments, the roughened surface can comprise defined features having a particular size, for example hemispherical features, pyramidal features, barrel-shaped features, cylindrical features, and the like, or a combination comprising at least one of the foregoing.

The integrated substrate also comprises a light extraction layer. The light extraction layer is disposed on the first surface of the substrate, which can optionally be a roughened surface, as described above. The light extraction layer comprises a polyimide and a plurality of nanoparticles.

Polyimides comprise more than 1, for example 10 to 1000, or 10 to 500, or 10 to 100, structural units of formula (1)

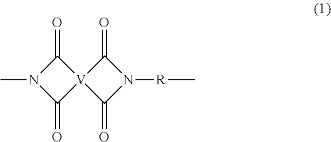

wherein each V is the same or different, and is a substituted or unsubstituted tetravalent C₄₋₄₀ hydrocarbon group, for example a substituted or unsubstituted C₆₋₂₀ aromatic hydrocarbon group, a substituted or unsubstituted, straight or branched chain, saturated or unsaturated C₂₋₂₀ aliphatic group, or a substituted or unsubstituted C₄₋₈ cycloalkylene group or a halogenated derivative thereof, in particular a substituted or unsubstituted C₆₋₂₀ aromatic hydrocarbon group. Exemplary aromatic hydrocarbon groups include any of those of the formulas

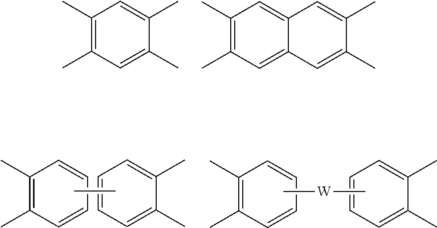

wherein W is —O—, —S—, —C(O)—, —SO₂—, —SO—, —C_{y}H_{2y}— wherein y is an integer from 1 to 5 or a halogenated derivative thereof (which includes perfluoroalkylene groups).

Each R in formula (1) is the same or different, and is a substituted or unsubstituted divalent organic group, such as a C₆₋₂₀ aromatic hydrocarbon group or a halogenated derivative thereof, a straight or branched chain C₂₋₂₀ alkylene group or a halogenated derivative thereof, a C₃₋₈ cycloalkylene group or halogenated derivative thereof, in particular a divalent group of formulas (2)

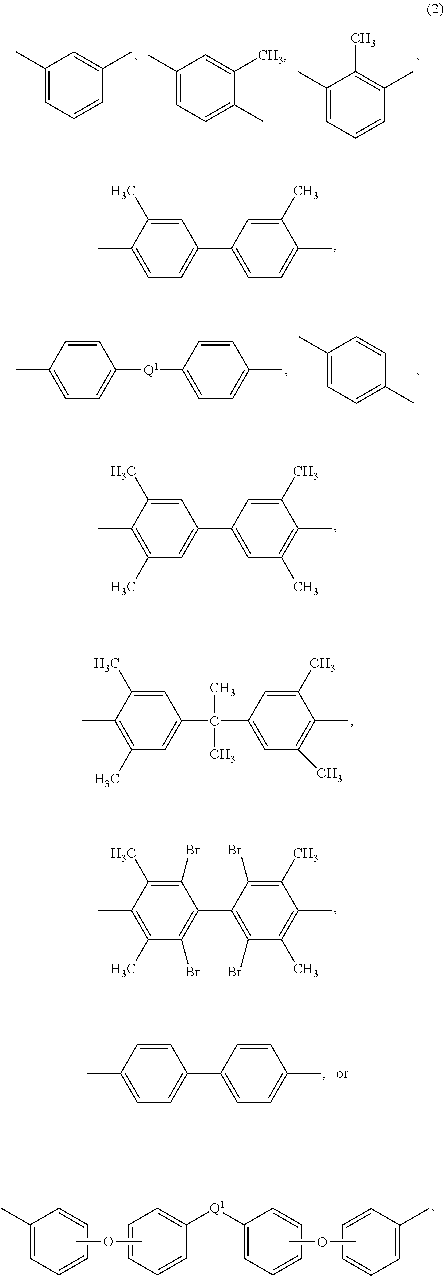

wherein Q¹ is —O—, —S—, —C(O)—, —SO₂—, —SO—, —C_{y}H_{2y}— wherein y is an integer from 1 to 5 or a halogenated derivative thereof (which includes perfluoroalkylene groups), or —(C₆H₁₀)_{z}— wherein z is an integer from 1 to 4. A combination of different R groups can be present. In some embodiments R is m-phenylene, p-phenylene, or a diaryl sulfone, in particular bis(4,4′-phenylene)sulfone, bis(3,4′-phenylene)sulfone, bis(3,3′-phenylene)sulfone, or a combination comprising at least one of the foregoing.

The polyimide can be prepared according to any of the methods that are well known to those skilled in the art, including the reaction of a dianhydride of formula (3) or a chemical equivalent thereof, with an organic diamine of formula (4)

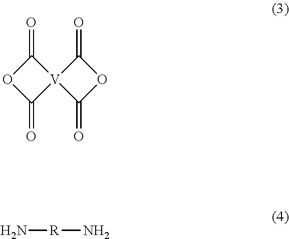

wherein V and R are defined as described above. Copolymers of polyimides can be manufactured using a combination of a dianhydride of formula (3) and a different dianhydride. In some embodiments, exemplary tetravalent linkers V can include

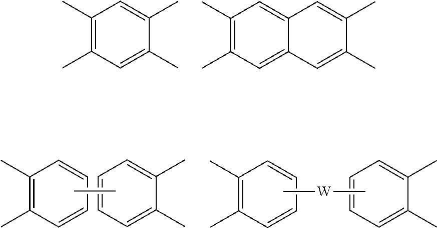

wherein W is —O—, —S—, —C(O)—, —SO₂—, —SO—, —C_{y}H_{2y}— wherein y is an integer from 1 to 5 or a halogenated derivative thereof (which includes perfluoroalkylene groups). In some embodiments, the dianhydride can be pyromellitic dianhydride.

In some embodiments, examples of organic diamines include hexamethylenediamine, polymethylated 1,6-n-hexanediamine, heptamethylenediamine, octamethylenediamine, nonamethylenediamine, decamethylenediamine, 1,12-dodecanediamine, 1,18-octadecanediamine, 3-methylheptamethylenediamine, 4,4-dimethylheptamethylenediamine, 4-methylnonamethylenediamine, 5-methylnonamethylenediamine, 2,5-dimethylhexamethylenediamine, 2,5-dimethylheptamethylenediamine, 2, 2-dimethylpropylenediamine, N-methyl-bis (3-aminopropyl) amine, 3-methoxyhexamethylenediamine, 1,2-bis(3-aminopropoxy) ethane, bis(3-aminopropyl) sulfide, 1,4-cyclohexanediamine, bis-(4-aminocyclohexyl) methane, m-phenylenediamine, p-phenylenediamine, 2,4-diaminotoluene, 2,6-diaminotoluene, m-xylylenediamine, p-xylylenediamine, 2-methyl-4,6-diethyl-1,3-phenylene-diamine, 5-methyl-4,6-diethyl-1,3-phenylene-diamine, benzidine, 3,3′-dimethylbenzidine, 3,3′-dimethoxybenzidine, 1,5-diaminonaphthalene, bis(4-aminophenyl) methane, bis(2-chloro-4-amino-3,5-diethylphenyl) methane, bis(4-aminophenyl) propane, 2,4-bis(p-amino-t-butyl) toluene, bis(p-amino-t-butylphenyl) ether, bis(p-methyl-o-aminophenyl) benzene, bis(p-methyl-o-aminopentyl) benzene, 1, 3-diamino-4-isopropylbenzene, bis(4-aminophenyl) sulfide, bis-(4-aminophenyl) sulfone (also known as 4,4′-diaminodiphenyl sulfone (DDS)), and bis(4-aminophenyl) ether. Any regioisomer of the foregoing compounds can be used. Combinations of these compounds can also be used. In some embodiments the organic diamine is m-phenylenediamine, p-phenylenediamine, 4,4′-diaminodiphenyl sulfone, or a combination comprising at least one of the foregoing.

In some embodiments, the polyimide is prepared from at least one aromatic diamine and at least one aromatic dianhydride. In some embodiments, the polyimide of the light extraction layer is not a halogen-containing polyimide, preferably the polyimide excludes a fluorine-containing polyimide. In some embodiments, the polyimide excludes repeating units derived from a cycloaliphatic dianhydride.

The polyimides can have a melt index of 0.1 to 10 grams per minute (g/min), as measured by American Society for Testing Materials (ASTM) D1238 at 340 to 370° C., using a 6.7 kilogram (kg) weight. In some embodiments, the polyimide has a weight average molecular weight (Mw) of 1,000 to 150,000 grams/mole (Dalton), as measured by gel permeation chromatography, using polystyrene standards. In some embodiments the polyimide has an Mw of 10,000 to 80,000 Daltons. Such polyimides typically have an intrinsic viscosity greater than 0.2 deciliters per gram (dl/g), or, more specifically, 0.35 to 0.7 dl/g as measured in m-cresol at 25° C.

The polyimide has a glass transition temperature of greater than 200 to 350° C., preferably 250 to 350° C., more preferably 300 to 350° C. In some embodiments, the polyimide further exhibits one or more of the following properties.

In some embodiments, the polyimide has a yellowness index of less than 10, preferably 1 to 5, determined at a thickness of 25 millimeters according to ASTM D1925.

In some embodiments, the polyimide has a coefficient of thermal expansion of 30 to 60 parts per million per ° C. (ppm/° C.), for example 40 to 60 ppm/° C., for example 48 to 52 ppm/° C., determined according to ASTM E 831.

In some embodiments, the polyimide has a transmission of greater than or equal to 90%, determined at a thickness of 25 micrometers according to ASTM D1003.

In some embodiments, the polyimide has a refractive index of 1.50 to 1.75, preferably 1.5 to 1.7, more preferably 1.6 to 1.7, even more preferably 1.6 to 1.65.

In addition to the polyimide, the light extraction layer also includes a plurality of nanoparticles. The nanoparticles have one or more dimensions that are less than or equal to 100 nanometers. The nanoparticles are preferably dispersed in the polyimide of the light extraction layer, and, without wishing to be bound by theory, can serve to further increase the refractive index of the light extraction light for improved light extraction. In some embodiments, the nanoparticles preferably comprise inorganic oxides, for example, titanium dioxide, zirconium dioxide, silicon dioxide, aluminum dioxide, tungsten oxide, tantalum pentaoxide, yttrium oxide, and the like, or a combination comprising at least one of the foregoing inorganic oxides. In some embodiments, the nanoparticles comprise titanium dioxide, zirconium dioxide, or a combination comprising at least one of the foregoing.

In some embodiments, the nanoparticles are present in the light extraction layer in an amount of greater than 5 to 95 weight percent, or 10 to 90 weight percent, or 50 to 90 weight percent, based on the total weight of the light extraction layer.

The light extraction layer comprising the polyimide and the plurality of nanoparticles can have a refractive index of 1.7 to 2.0, preferably 1.8 to 1.9. The light extraction layer can have a thickness of 0.1 to 10 micrometers, or 0.5 to 5 micrometers, or 0.1 to 1 micrometer.

In some embodiments, the integrated substrate can further include a transparent electrode disposed on the light extraction layer on a side opposite the substrate. In other words, the light extraction layer can be sandwiched between the transparent electrode (when present) and the first surface of the substrate. In some embodiments, the transparent electrode can be selected such that a 5 micrometer thick sample of the conductive layer transmits greater than 80% of visible light as determined according to ASTM D1003-00. The transparent electrode can comprise indium tin oxide, aluminum zinc oxide, indium zinc oxide, cadmium tin oxide, gallium zinc oxide, conductive nanowires, conductive nanomesh (e.g., formed from conductive metal nanoparticles) and the like, or a combination comprising at least one of the foregoing. In some embodiments, the transparent electrode preferably comprises indium tin oxide. When present, the transparent electrode can have a thickness of 0.1 to 10 micrometers, preferably 0.1 to 5 micrometers, more preferably 0.1 to 1 micrometer.

In some embodiments, the integrated substrate can further include a microlens array disposed on the second surface of the substrate. The microlens array is preferably a convex microlens array (e.g., having a hemispherical shape). When present, the microlens array can further improve the light extraction efficiency of a light emitting device.

In some embodiments, the integrated substrate can further include an adhesive layer disposed between the microlens array and the second surface of the substrate. When present, the adhesive layer can comprise an optically clear adhesive, for example, epoxy, acrylate, amine, urethane, silicone, thermal plastic urethane, ethyl vinyl acetate, hindered amine light stabilizer free ethyl vinyl acetate (HALS free EVA), or a combination comprising at least one of the foregoing. The adhesive can be applied using any suitable process including, but not limited to, roll lamination, roller coating, screen printing, spreading, spray coating, spin coating, dip coating, and the like, or a combination comprising at least one of the foregoing techniques.

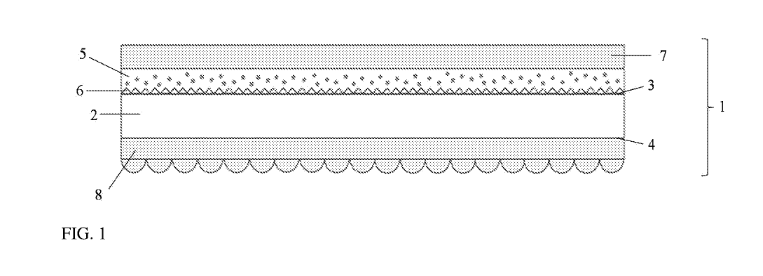

In an embodiment, an integrated substrate can be as shown in FIG. 1. FIG. 1 shows a cross-sectional view of an integrated substrate (1) comprising a substrate (2) having a first surface (3) and a second surface opposite the first surface (4). The first surface (3) can optionally be roughened, and thus include regular or irregular microstructure features (6). A light extraction layer (5) is disposed on the first surface (3) of the substrate. A transparent electrode (7) can be disposed on the light extraction layer (5) on a side opposite the substrate (2). Additionally, a microlens array (8) can be applied to the second surface (4) of the substrate (2).

The integrated substrate can be manufactured by a method comprising applying the light extraction layer to the first surface of the substrate. The light extraction layer can be prepared by any techniques that are generally known for producing polymer films, for example, by a solution casting process such as slot die coating, spin coating, dip coating, and the like (including solution casting directly on the first surface of the substrate) or by extruding the light extraction layer. In some embodiments, for example when the light extraction layer is extruded to provide a film, the light extraction layer can subsequently be laminated to the substrate under heat and pressure. In some embodiments, when a microlens array is included with the integrated substrate, the microlens array can be applied to the second surface of the substrate, preferably where the microlens array is adhered to the second surface of the substrate via an adhesive layer. In some embodiments, where a transparent electrode is present, the method further comprises applying the transparent electrode to the light extraction layer. Applying the transparent electrode can be by a sputtering process or a solution coating process.

An optical device comprising the integrated substrate represents another aspect of the present disclosure. An optical device can include an integrated substrate comprising a substrate having a first surface and a second surface opposite the first surface, and a light extraction layer disposed on the first surface of the substrate, wherein the light extraction layer comprises the polyimide and plurality of nanoparticles, as described above. The light extraction layer has a refractive index of 1.7 to 2.0, preferably 1.8 to 1.9.

The optical device further includes an optical component disposed on the light extraction layer on a side opposite the substrate. In some embodiments, the optical component can be a light emitting diode, an organic light emitting diode, or a quantum dot light emitting diode. In some embodiments, the optical component is an organic light emitting diode comprising a first transparent electrode disposed on the light extraction layer on a side opposite the substrate, an organic light emitting layer, and a second electrode, wherein the organic light emitting layer is disposed between the first and second electrodes. The first transparent electrode can be as described above. For example, the first transparent electrode of the optical component can comprise indium tin oxide, aluminum zinc oxide, indium zinc oxide, cadmium tin oxide, gallium zinc oxide, conductive nanowires, conductive nanomesh (e.g., formed from conductive metal nanoparticles) and the like, or a combination comprising at least one of the foregoing. In some embodiments, the transparent electrode preferably comprises indium tin oxide. When present, the transparent electrode can have a thickness of 0.1 to 10 micrometers, preferably 0.1 to 5 micrometers, more preferably 0.1 to 1 micrometer. The second electrode is preferably a reflective material, for example, titanium, tantalum, molybdenum, aluminum, neodymium, gold, silver, copper, and the like, or a combination comprising at least one of the foregoing reflective materials. The light emitting layer can be selected based on the desired color of the emitted light. The emitted color of the light generally depends on the combination of a dopant and a host material included in the light emitting layer. For example, in some embodiments, the host material in the organic light emitting layer can be tris(8-hydroxy quinoline) aluminum (III) (Alq3), and the dopant thereof can be organic material including red dopants such as 4-dicyanomethylene-2-tert-butyl-6-(1,1,7,7-tetramethyljulolidin-4-yl-vinyl)-4H-pyran (DCJTB), green dopants such as 10-(2-Benzothiazolyl)-2,3,6,7-tetrahydro-1,1,7,7-tetramethyl-1H,5H, 11H-(1)benzopyrano (6,7-8-I,j)quinolizin-11-one, (C545T), or blue dopants such as 4,4′-bis(2,2′-diphenylvinyl)-1,1′-biphenyl (DPVBi) or spiro-DPVBi. In some embodiments, the host material of the organic light emitting layer can be organic molecules including anthracene series such as 2-methyl-9,10-di(2-naphthyl)anthracene (MADN) or carbazole series such as 4,4′-bis(carbazole-9-yl)-biphenyl (CBP), N,N-′-dicarbazolyl-3,5-benzene (mCP), and tris(carbazol-9-yl)benzene (tCP). The corresponding dopant of the organic host material can be a metal dopant including iridium complexes such as bis(1-phenylisoquinoline)acetylacetonate iridium (PlQIr(acac)), bis(2-phenylquinolyl-N,C2) acetylacetonate iridium(III) (PQIr(acac)), or bis(2-phenyl quinolyl-N,C2′)acetylacetonate iridium(III) (PQIr), or platinum complexes such as platinum octaethylporphine (PtOEP). The iridium complex applied to emit green light may be tris[2-(2-pyridinyl)phenyl-C,N]-iridium (abbreviated Ir(ppy)₃). A hole injection layer, a hole transport layer, or other layers can be disposed between the organic light emitting layer and a positive electrode (e.g. the first electrode or the second electrode), and an electron injection layer, an electron transport layer, or other layers can be disposed between the organic light emitting layer and a negative electrode (e.g. the first electrode or the second electrode), respectively, to further enhance the illumination efficiency of the optical device.

In some embodiments, the optical component is a quantum dot light emitting diode comprising a first transparent electrode disposed on the light extraction layer on a side opposite the substrate, a quantum dot light emitting layer, and a second electrode, wherein the quantum dot light emitting layer is disposed between the first and second electrodes. The quantum dot light emitting layer comprises semiconducting nanocrystals, for example, comprising CdSe, CdS, CdTe, ZnSe, ZnTe, ZnS, HgTe, InAs, InP, GaAs, or a combination comprising at least one of the foregoing. The quantum dot light emitting layer can have a thickness of 5 to 25 nanometers, and can be deposited, for example, by a fluid-based method, such as spin coating, printing, casting and spraying of a suspension of the quantum dots, and removing the liquid suspending vehicle to form the quantum dot light emitting layer.

The optical device can optionally further comprise a microlens array disposed on the second surface of the substrate, preferably wherein the microlens array is convex. As discussed above, in some embodiments, the microlens array can be adhered to the second surface of the substrate via an adhesive.

The optical device including the integrated substrate can advantageously exhibit increased light extraction efficiency, compared to an optical device not including the integrated substrate according the present disclosure. In some embodiments, the optical device can exhibit an out-coupling efficiency of 20 to 50 percent.

The present inventors have unexpectedly discovered that an improved integrated substrate can be prepared from a substrate and a light extraction layer comprising a polyimide and a plurality of nanoparticles, providing a high refractive index light extraction layer, which can enhance the light out-coupling efficiency of an electroluminescent device. Furthermore, the use of the high heat, transparent polyimides renders the integrated substrates compatible with a high temperature sputtering process that can be used to deposit a conductive material (e.g., a transparent electrode (anode) comprising indium tin oxide), and further prevent or reduce device degradation due to heat generated from the device itself. Thus the integrated substrates described herein are advantageously compatible with temperatures of 120 to 400° C.

Accordingly, the integrated substrates, method of manufacturing, and optical devices comprising the integrated substrates represent a significant improvement.

The integrated substrates, methods, and devices of the present disclosure are further illustrated by the following embodiments, which are non-limiting.

### Embodiment 1

An integrated substrate comprising, a substrate having a first surface and a second surface opposite the first surface; and a light extraction layer disposed on the first surface of the substrate, the light extraction layer comprising a polyimide having a glass transition temperature of greater than 200 to 350° C., preferably 250 to 350° C., more preferably 300 to 350° C.; and a plurality of nanoparticles; wherein the light extraction layer has a refractive index of 1.7 to 2.0, preferably 1.8 to 1.9.

### Embodiment 2

The integrated substrate of embodiment 1, wherein the substrate comprises a glass substrate.

### Embodiment 3

The integrated substrate of embodiment 1 or 2, wherein the substrate comprises a polymer substrate comprising polyester, polycarbonate, polyether ether ketone, polyarylate, cycloolefin polymer, or a combination comprising at least one of the foregoing, preferably polyethylene terephthalate, polyethylene naphthalate, polynorbornene, polyethersulfone, or a combination comprising at least one of the foregoing.

### Embodiment 4

The integrated substrate of any one or more of embodiments 1 to 3, wherein the first surface of the substrate is a roughened surface.

### Embodiment 5

The integrated substrate of any one or more of embodiments 1 to 4, wherein the substrate has a thickness of 10 micrometers to 1 millimeter, preferably 50 to 500 micrometers, more preferably 100 to 250 micrometers.

### Embodiment 6

The integrated substrate of any one or more of embodiments 1 to 5, wherein the polyimide comprises repeating units of the formula

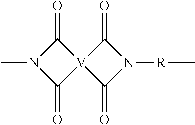

wherein R is independently at each occurrence a substituted or unsubstituted C₂₋₂₀ divalent organic group; and V is independently at each occurrence a substituted or unsubstituted C₆₋₂₀ aromatic hydrocarbon group.

### Embodiment 7

The integrated substrate of embodiment 6, wherein R is a divalent group of the formula

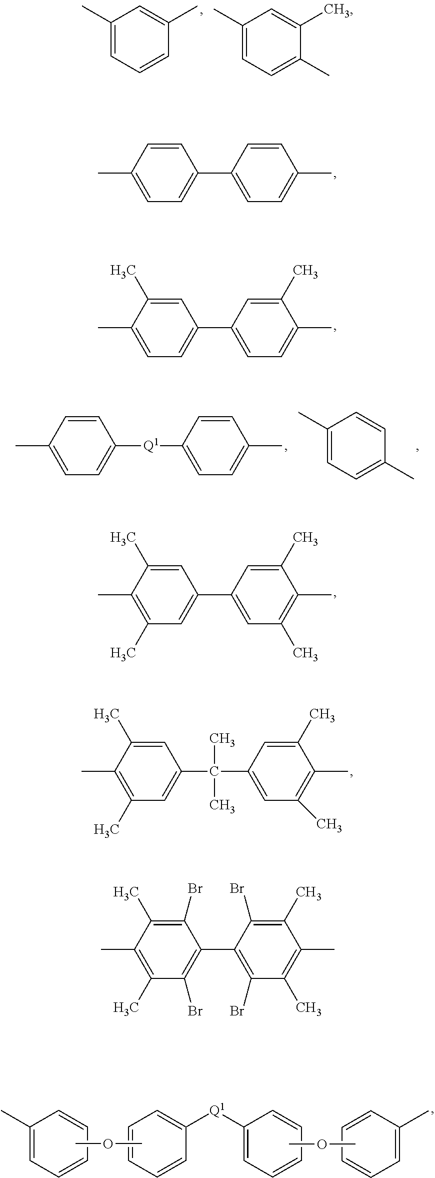

wherein Q¹ is —O—, —S—, —C(O)—, —SO₂—, —SO—, —C_{y}H_{2y}—, and a halogenated derivative thereof, wherein y is an integer from 1 to 5, or —(C₆H₁₀)_{z}— wherein z is an integer from 1 to 4; and V is a tetravalent group of the formula

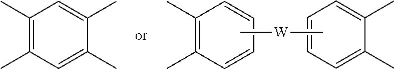

wherein W is a single bond, —S—, —C(O)—, —SO₂—, —SO—, or —C_{y}H_{2y}— wherein y is an integer from 1 to 5 or a halogenated derivative thereof.

### Embodiment 8

The integrated substrate of any one or more of embodiments 1 to 7, wherein the polyimide is prepared from at least one aromatic diamine and at least one aromatic dianhydride.

### Embodiment 9

The integrated substrate of any one or more of embodiments 1 to 8, wherein the polyimide has one or more of the following properties: a yellowness index of less than 10, preferably 1 to 5, determined at a thickness of 25 micrometers according to ASTM D1925; a coefficient of thermal expansion of 30 to 60 parts per million per ° C., determined according to ASTM E 831; a transmission of greater than or equal to 90%, determined at a thickness of 25 micrometers according to ASTM D1003; and a refractive index of 1.50 to 1.75.

### Embodiment 10

The integrated substrate of any one or more of embodiments 1 to 9, wherein the nanoparticles have one or more dimensions of less than or equal to 100 nanometers.

### Embodiment 11

The integrated substrate of any one or more of embodiments 1 to 10, wherein the nanoparticles comprise inorganic oxides.

### Embodiment 12

The integrated substrate of any one or more of embodiments 1 to 11, wherein the nanoparticles comprise titanium dioxide, zirconium dioxide, silicon dioxide, aluminum dioxide, tungsten oxide, tantalum pentaoxide, yttrium oxide, or a combination comprising at least one of the foregoing, preferably titanium dioxide, zirconium dioxide, or a combination comprising at least one of the foregoing.

### Embodiment 13

The integrated substrate of any one or more of embodiments 1 to 12, wherein the nanoparticles are present in the light extraction layer in an amount of greater than 5 to 95 weight percent, or 10 to 90 weight percent, or 50 to 90 weight percent, based on the total weight of the light extraction layer.

### Embodiment 14

The integrated substrate of any one or more of embodiments 1 to 13, wherein the light extraction layer has a thickness of 0.1 to 10 micrometers, preferably 0.5 to 5 micrometers.

### Embodiment 15

The integrated substrate of any one or more of embodiments 1 to 14, further comprising a transparent electrode disposed on the light extraction layer on a side opposite the substrate, preferably wherein the transparent electrode comprises indium tin oxide, indium zinc oxide, aluminum zinc oxide, gallium zinc oxide, conductive nanowires, conductive nanomesh, or a combination comprising at least one of the foregoing.

### Embodiment 16

The integrated substrate of any one or more of embodiments 1 to 15, further comprising a microlens array disposed on the second surface of the substrate, preferably wherein the microlens array is convex.

### Embodiment 17

The integrated substrate of embodiment 16, wherein the integrated substrate further comprises an adhesive layer disposed between the microlens array and the second surface of the substrate.

### Embodiment 18

A method of manufacturing the integrated substrate of any one or more of embodiments 1 to 17, the method comprising, applying the light extraction layer to the first surface of the substrate.

### Embodiment 19

The method of embodiment 18, further comprising applying a microlens array to the second surface of the substrate.

### Embodiment 20

The method of embodiment 18 or 19, further comprising applying a transparent electrode to the light extraction layer on a side opposite the substrate.

### Embodiment 21

An optical device comprising the integrated substrate of any one or more of embodiments 1 to 17.

### Embodiment 22

An optical device comprising, an integrated substrate comprising, a substrate having a first surface and a second surface; a light extraction layer disposed on the first surface of the substrate, the light extraction layer comprising a polyimide having a glass transition temperature of greater than 200 to 350° C., preferably 250 to 350° C., more preferably 300 to 350° C.; and a plurality of nanoparticles; wherein the light extraction layer has a refractive index of 1.7 to 2.0, preferably 1.8 to 1.9; and an optical component disposed on the light extraction layer on a side opposite the substrate.

### Embodiment 23

The optical device of embodiment 22, wherein the optical component is a light emitting diode, an organic light emitting diode, or a quantum dot light emitting diode.

### Embodiment 24

The optical device of embodiment 22 or 23, wherein the optical component is an organic light emitting diode comprising a first transparent electrode disposed on the light extraction layer on a side opposite the substrate; an organic light emitting layer; and a second electrode, wherein the organic light emitting layer is disposed between the first and second electrodes.

### Embodiment 25

The optical device of any one or more of embodiments 22 to 24, further comprising a microlens disposed on the second surface of the substrate, preferably wherein the microlens is convex.

The compositions, methods, and articles can alternatively comprise, consist of, or consist essentially of, any appropriate components or steps herein disclosed. The compositions, methods, and articles can additionally, or alternatively, be formulated so as to be devoid, or substantially free, of any steps, components, materials, ingredients, adjuvants, or species that are otherwise not necessary to the achievement of the function or objectives of the compositions, methods, and articles.

All ranges disclosed herein are inclusive of the endpoints, and the endpoints are independently combinable with each other. “Combinations” is inclusive of blends, mixtures, alloys, reaction products, and the like. The terms “first,” “second,” and the like, do not denote any order, quantity, or importance, but rather are used to distinguish one element from another.

The terms “a” and “an” and “the” do not denote a limitation of quantity, and are to be construed to cover both the singular and the plural, unless otherwise indicated herein or clearly contradicted by context. “Or” means “and/or” unless clearly stated otherwise. Reference throughout the specification to “some embodiments”, “an embodiment”, and so forth, means that a particular element described in connection with the embodiment is included in at least one embodiment described herein, and may or may not be present in other embodiments. In addition, it is to be understood that the described elements may be combined in any suitable manner in the various embodiments.

Unless defined otherwise, technical and scientific terms used herein have the same meaning as is commonly understood by one of skill in the art to which this application belongs. All cited patents, patent applications, and other references are incorporated herein by reference in their entirety. However, if a term in the present application contradicts or conflicts with a term in the incorporated reference, the term from the present application takes precedence over the conflicting term from the incorporated reference.

The term “alkyl” means a branched or straight chain, unsaturated aliphatic hydrocarbon group, e.g., methyl, ethyl, n-propyl, i-propyl, n-butyl, s-butyl, t-butyl, n-pentyl, s-pentyl, and n- and s-hexyl. “Alkenyl” means a straight or branched chain, monovalent hydrocarbon group having at least one carbon-carbon double bond (e.g., ethenyl (—HC═CH₂)). “Alkoxy” means an alkyl group that is linked via an oxygen (i.e., alkyl-O—), for example methoxy, ethoxy, and sec-butyloxy groups. “Alkylene” means a straight or branched chain, saturated, divalent aliphatic hydrocarbon group (e.g., methylene (—CH₂—) or, propylene (—(CH₂)₃—)). “Cycloalkylene” means a divalent cyclic alkylene group, —CₙH₂ₙ₋ₓ, wherein x is the number of hydrogens replaced by cyclization(s). “Cycloalkenyl” means a monovalent group having one or more rings and one or more carbon-carbon double bonds in the ring, wherein all ring members are carbon (e.g., cyclopentyl and cyclohexyl). “Aryl” means an aromatic hydrocarbon group containing the specified number of carbon atoms, such as phenyl, tropone, indanyl, or naphthyl. The prefix “halo” means a group or compound including one more of a fluoro, chloro, bromo, or iodo substituent. A combination of different halo groups (e.g., bromo and fluoro), or only chloro groups can be present. The prefix “hetero” means that the compound or group includes at least one ring member that is a heteroatom (e.g., 1, 2, or 3 heteroatom(s)), wherein the heteroatom(s) is each independently N, O, S, Si, or P. “Substituted” means that the compound or group is substituted with at least one (e.g., 1, 2, 3, or 4) substituents that can each independently be a C₁₋₉ alkoxy, a C₁₋₉ haloalkoxy, a nitro (—NO₂), a cyano (—CN), a C₁₋₆ alkyl sulfonyl (—S(═O)₂-alkyl), a C₆₋₁₂ aryl sulfonyl (—S(═O)₂-aryl) a thiol (—SH), a thiocyano (—SCN), a tosyl (CH₃C₆H₄SO₂—), a C₃₋₁₂ cycloalkyl, a C₂₋₁₂ alkenyl, a C₅₋₁₂ cycloalkenyl, a C₆₋₁₂ aryl, a C₇₋₁₃ arylalkylene, a C₄₋₁₂ heterocycloalkyl, and a C₃₋₁₂ heteroaryl instead of hydrogen, provided that the substituted atom's normal valence is not exceeded. The number of carbon atoms indicated in a group is exclusive of any substituents. For example —CH₂CH₂CN is a C₂ alkyl group substituted with a nitrile.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. An integrated substrate comprising,
a substrate having a first surface and a second surface opposite the first surface; and
a light extraction layer disposed on the first surface of the substrate, the light extraction layer comprising
a polyimide having a glass transition temperature of greater than 200 to 350° C.; and
a plurality of nanoparticles;
wherein the light extraction layer has a refractive index of 1.7 to 2.0.

2. The integrated substrate of claim 1, wherein the substrate comprises a glass substrate.

3. The integrated substrate of claim 1, wherein the substrate comprises a polymer substrate comprising polyester, polycarbonate, polyether ether ketone, polyarylate, cycloolefin polymer, or a combination comprising at least one of the foregoing.

4. The integrated substrate of claim 1, wherein the first surface of the substrate is a roughened surface.

5. The integrated substrate of claim 1, wherein the substrate has a thickness of 10 micrometers to 1 millimeter.

6. The integrated substrate of claim 1, wherein the polyimide comprises repeating units of the formula 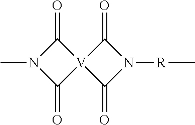
wherein
R is independently at each occurrence a substituted or unsubstituted C₂₋₂₀ divalent organic group; and
V is independently at each occurrence a substituted or unsubstituted C₆₋₂₀ aromatic hydrocarbon group.

7. The integrated substrate of claim 6,
wherein R is a divalent group of the formula 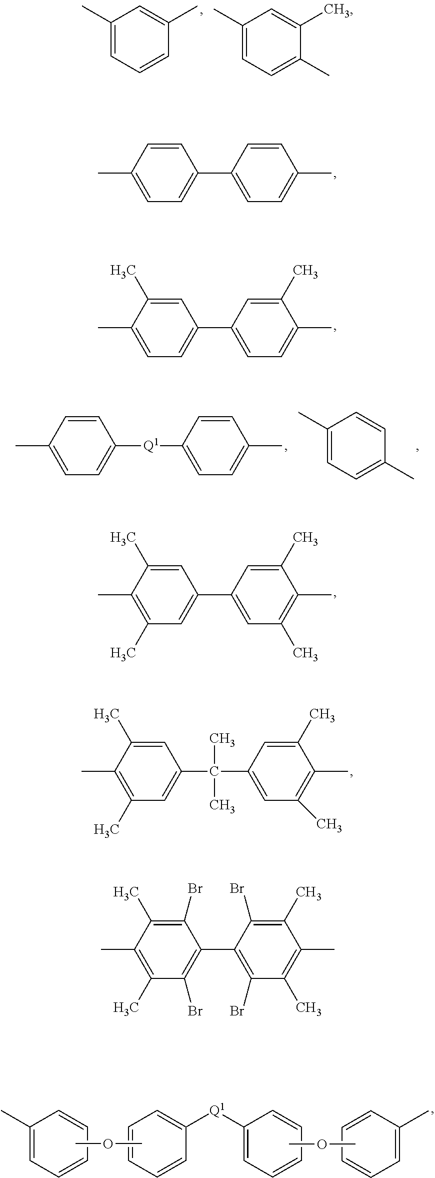
wherein Q¹ is —O—, —S—, —C(O)—, —SO₂—, —SO—, —C_{y}H_{2y}—, and a halogenated derivative thereof,
wherein y is an integer from 1 to 5, or —(C₆H₁₀)_{z}— wherein z is an integer from 1 to 4; and
V is a tetravalent group of the formulas 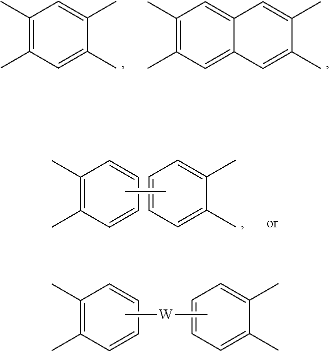
wherein W is a single bond, —S—, —C(O)—, —SO₂—, —SO—, or —C_{y}H_{2y}— wherein y is an integer from 1 to 5 or a halogenated derivative thereof.

8. The integrated substrate of claim 1, wherein the polyimide has one or more of the following properties:
a yellowness index of less than 10, determined at a thickness of 25 micrometers according to ASTM D1925;
a coefficient of thermal expansion of 30 to 60 parts per million per ° C., determined according to ASTM E 831;
a transmission of greater than or equal to 90%, determined at a thickness of 25 micrometers according to ASTM D1003; and
a refractive index of 1.50 to 1.75.

9. The integrated substrate of claim 1, wherein the nanoparticles comprise inorganic oxides.

10. The integrated substrate of claim 1, wherein the nanoparticles are present in the light extraction layer in an amount of greater than 5 to 95 weight percent, based on the total weight of the light extraction layer.

11. The integrated substrate of claim 1, wherein the light extraction layer has a thickness of 0.1 to 10 micrometers.

12. The integrated substrate of claim 1, further comprising one or both of
a transparent electrode disposed on the light extraction layer on a side opposite the substrate; and
a microlens array disposed on the second surface of the substrate.

13. The integrated substrate of claim 12, wherein the integrated substrate further comprises an adhesive layer disposed between the microlens array and the second surface of the substrate.

14. A method of manufacturing the integrated substrate of claim 1, the method comprising,
applying the light extraction layer to the first surface of the substrate.

15. The method of claim 14, further comprising applying a microlens array to the second surface of the substrate.

16. The method of claim 14, further comprising applying a transparent electrode to the light extraction layer on a side opposite the substrate.

17. An optical device comprising the integrated substrate of claim 1.

18. An optical device comprising,
an integrated substrate comprising,
a substrate having a first surface and a second surface;
a light extraction layer disposed on the first surface of the substrate, the light extraction layer comprising
a polyimide having a glass transition temperature of greater than 200 to 350° C.; and
a plurality of nanoparticles;
wherein the light extraction layer has a refractive index of 1.7 to 2.0; and
an optical component disposed on the light extraction layer on a side opposite the substrate.

19. The optical device of claim 18, wherein the optical component is a light emitting diode, an organic light emitting diode, or a quantum dot light emitting diode.

20. The optical device of claim 18, further comprising a microlens disposed on the second surface of the substrate.
